(19) United States
(12) Patent Application Publication
(10) Pub. No.: US 2025/0363404 A1
(43) Pub. Date: Nov. 27, 2025

(54) QUANTUM INFORMATION PROCESSING SYSTEM

(71) Applicant: Oxford Ionics Limited, Begbroke (GB)

(72) Inventors: Maciej MALINOWSKI, Begbroke (GB); David ALLCOCK, Begbroke (GB); Thomas HARTY, Begbroke (GB); Chris BALLANCE, Begbroke (GB)

(73) Assignee: Oxford Ionics Limited, Begbroke (GB)

(21) Appl. No.: 19/109,986

(22) PCT Filed: Sep. 8, 2023
(86) PCT No.: PCT/GB2023/052331

§ 371 Date: Mar. 7, 2025

(30) Foreign Application Priority Data
Sep. 9, 2022 (GB) 2213238.5

(51) Int. Cl. G06N 10/40

(52) U.S. Cl. CPC G06N 10/40

(57) ABSTRACT

A quantum information processing system is disclosed. The system comprises a charged particle trap comprising a substrate and a set of electrodes supported on the substrate, and a control system for controlling the charged particle trap, for applying biases to the set of electrodes for trapping at least one charged particle and performing at least one quantum logic gate on the at least one charged particle. The electrodes include at least one current-carrying electrode which is formed of a superconducting material. The control system is configured to pass a current through the at least one current-carrying electrode having a peak current of at least 1 A.

### FIELD

The present invention relates to a quantum information processing system.

### BACKGROUND

Low-error quantum gates on trapped-ion systems can be performed using magnetic fields, as described in, for example, T. P. Harty et. al.: “High-fidelity preparation, gates, memory and readout of a trapped-ion quantum bit”: https://arxiv.org/abs/1403.1524 (2014) and R. Srinivas et al.: “High-fidelity laser-free universal control of two trapped ion qubits”: https://arxiv.org/pdf/2102.12533.pdf (2021).

### SUMMARY

According to a first aspect of the present invention there is provided a quantum information processing system which comprises a charged particle trap comprising a substrate and a set of electrodes supported on the substrate, and a control system for controlling the charged particle trap and for applying biases to the set of electrodes for trapping at least one charged particle and performing at least one quantum logic gate on the at least one charged particle. The electrodes include at least one current-carrying electrode which is formed of a superconducting material, and the control system is configured to pass a current through the at least one current-carrying electrode a peak current of at least 1 A.

This can help to reduce power dissipation when trapping charged particles and performing quantum information processing, such as quantum logic gates, on the charged particles.

The at least one current-carrying electrode may have first and second ends. The at least one current-carrying electrode is preferably elongate. The first end of a current carrying wire may be connected to a bias source. The second end of the current carrying wire may be connected to the bias source, ground or a terminal load.

The control system may be configured to pass the current through the at least one current-carrying electrode having a frequency less than or equal to 1 GHz.

The at least one current-carrying electrode may have a thickness t of at least 0.3 μm.

The charged particles may be ions, such as calcium ions (such as ⁴⁰Ca⁺ or ⁴³Ca⁺). The charged particles may be atoms or molecules with net electric charge, or elementary charged particles, such as electrons or positrons.

The thickness t may be at least 0.5 μm or may be at least 1 μm.

The superconducting material may be rare-earth barium copper oxide, ReBCO, niobium or an alloy comprising niobium. The at least one current-carrying electrode may have a width w (which is transverse to the current) of between 5 and 500 μm.

The electrodes may include at least one electrode formed of normal metal.

There may be at least two current-carrying electrodes, for example, three current-carrying electrodes. The at least two current-carrying electrodes may have different widths. The control system may be configured to drive a respective current through each current-carrying electrode. The at least two currents may have different frequencies and/or different phases. The at least two currents may have different current values.

The charged particle trap may comprise a first layer of co-planar electrodes and a second layer of co-planar electrodes. The first layer of co-planar electrodes may be interposed between the substrate and second layer of co-planar electrodes.

The first layer of co-planar electrodes may include the at least one current-carrying electrode. The second layer of co-planar electrodes may include electrodes formed of normal metal.

The charged particle trap may further comprise a layer of dielectric material, such as silicon dioxide, interposed between the first layer of co-planar electrodes and the second layer of co-planar electrodes.

The set of electrodes may include a set of surface electrodes having a shielding effectiveness S=20 log₁₀[B0′/B1′]≤20 dB or <1 dB where B0′ would be the magnetic field gradient at a charged particle when trapped by the charged particle trap in absence of the set of surface electrodes, and B1′ would be the magnetic field gradient at a charged particle when trapped by the charged particle trap in the presence of the set of surface electrodes.

According to a second aspect of the present invention there is provided a method of operating the quantum information processing system. The method comprises trapping at least one charged particle in the trap, each charged particle providing a respective qubit, preparing initial qubit state(s) and applying a sequence of one or more gates to the qubit(s). Applying the sequence of one or more gates to the qubit(s) includes driving current(s) through the, or each, of the at least one current-carrying electrodes, the or each respective current having a frequency less than or equal to 1 GHz and a peak current of at least 1 A.

The method may further comprise reading out qubit state(s).

### BRIEF DESCRIPTION OF THE DRAWINGS

Certain embodiments of the present invention will now be described, by way of example, with reference to the accompanying drawings, in which:

FIG. 1 is a schematic view of a quantum information processing system comprising a first surface-electrode trap and a control system;

FIG. 2 is a schematic cross-sectional view of the first surface-electrode trap shown in FIG. 1 taken along the line A-A′;

FIG. 3 is a schematic cross-sectional view of a second surface-electrode trap;

FIG. 4 is a schematic cross-sectional view of a third surface-electrode trap;

FIG. 5 is a process flow diagram of a method of operating the quantum information processing system shown in FIG. 1; and

FIG. 6 shows a current-carrying electrode and control system in more detail.

### DETAILED DESCRIPTION OF CERTAIN EMBODIMENTS

### Introduction

T. P. Harty ibid. and R. Srinivas ibid. employ arrangements in which ions are trapped above a principal surface of a chip supporting conductive traces, and high currents (>1 A) are passed through the traces to generate strong near-field magnetic fields and magnetic field gradients. Although these arrangements have been used to perform ultra-low error single-qubit and two-qubit gates, power dissipation remains a challenge.

Although superconducting materials can be used in ion traps, they have only been used for electrodes which generate electric fields. Shannon X. Wang et al.: “Superconducting microfabricated ion traps” https://arxiv.org/pdf/1010.6108.pdf (2010), P. C. Holz et al.: “Electric field noise in a high-temperature superconducting surface ion trap” https://arxiv.org/pdf/2106.03945.pdf (2021), and J. Chiaverini and J. M. Sage: “Insensitivity of the rate of ion motional heating to trap-electrode material over a large temperature range”, Physical Review A, volume 89, page 012317 (2014) describe superconducting ion traps.

Superconducting materials have also been used a single-photon detector co-fabricated with a surface-electrode ion trap. S. L. Todaro et al.: “State Readout of a Trapped Ion Qubit Using a Trap-Integrated Superconducting Photon Detector”, Physical Review Letters, volume 126, 010501 (2021) describes a trap-integrated photon detector using a superconducting nanowire single-photon detector. The trap electrodes are made of electroplated gold on an intrinsic silicon substrate.

Although some superconductors have DC critical current densities which might allow them to pass high currents (>1 A) while remaining in a superconducting state, this ability degrades with increasing frequency. Moreover, although superconductors exist which exhibit high critical current densities, they tend to be harder to deposit and pattern, especially in a thick layer (>300 nm), and this can lead to divergence between the fabrication requirements of the trapping layer, and the fabrication requirements of high-critical current superconductors.

### Quantum Information Processing System 1

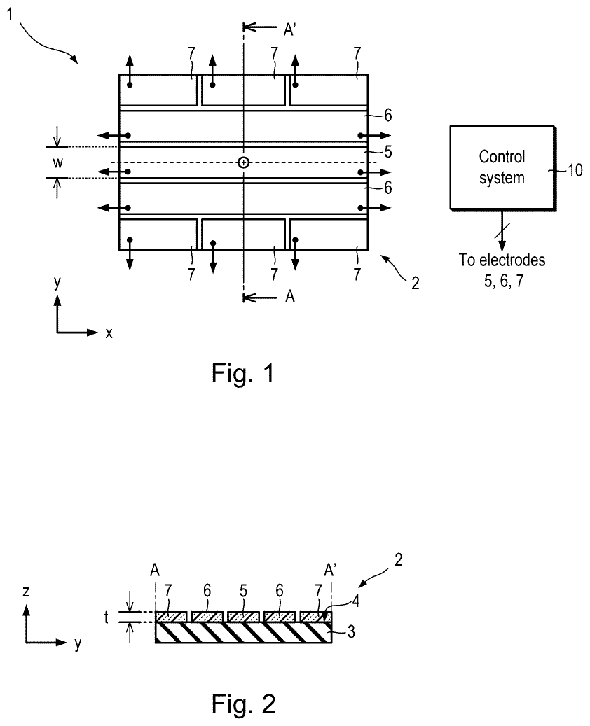

Referring to FIG. 1, a quantum information processing system 1 is shown which includes a first surface-electrode trap 2. The surface-electrode trap 2 comprises a substrate 3, for example, comprising silicon dioxide, having an upper surface 4 (or “principal surface”) supporting an arrangement of electrodes 5, 6, 7 which can be used to trap and control one or more charged particles 8 providing respective qubits.

The charged particle(s) 8 take the form of ion(s), such as calcium ions (for example, ⁴⁰Ca⁺ or ⁴³Ca⁺), although they may, however, take the form of atom(s) or molecule(s) with net electric charge, or elementary charged particle(s), such as electrons or positrons.

The surface-electrode trap 2 is housed in a cryogenic refrigerator (not shown) for cooling the surface-electrode trap 2 to a suitably low temperature T (e.g., below 77 K or 4.2 K). The surface-electrode trap 2 may be housed in a vacuum chamber (not shown), which provides an ultra-high vacuum environment allowing individual charged particles to be isolated. The system 1 also comprises a control system 10 for applying DC and AC biases to the electrodes 5, 6, 7 including a central electrode 5 through which so current can be passed to generate a magnetic field gradient. A current-carrying electrode is preferably elongate (i.e., longer than it is wide) having first and second ends. A current-carrying electrode may be referred to as a “conductive track”, “conductive trace” or simply “wire”. In the case the current-carrying electrode is formed from a superconducting material, the current-carrying electrode may also be referred to as a “superconducting track”, “superconducting trace” or simply “superconducting wire”. The first end may have or provide a first terminal (not shown) connected to a bias source (not shown), such as current source or a voltage source, in the control system 10, and the second end may have or provide a second terminal (not shown) connected to the bias source, to ground or to a terminal load allowing current to pass from the source through the wire. Examples of a quantum information processing system and surface-electrode traps can be found in WO 2021/205145 A1 which is incorporated herein by reference.

Referring also to FIG. 2, the central electrode 5 and, optionally, some or all of the other electrodes 6, 7 are formed of a suitable superconducting material, such as niobium or Rare-earth barium copper oxide (ReBCO), and have a sufficient thickness, t, and width, w, to support DC or low-frequency AC currents (0≤f≤1 GHz) having a peak magnitude of at least 1 A without exceeding critical current density, j_{c}. For example, the ReBCO may be YBCO. The central electrode 5 and, optionally, the others electrodes 6, 7 has (have) a thickness t of at least 0.3 μm, preferably at least 0.5 μm and more preferably at least 1 μm. The central electrode 5 and, optionally, the RF electrodes 6, has (have) a width, w, of between 5 and 500 μm, preferably between 10 and 100 μm transverse to the longitudinal axis 9.

One or more layers of material, such as a metal, may be included under or on top of the layer of superconducting material for providing a better surface for wirebonds, for promoting adhesion, for providing a diffusion barrier and/or provide a protective barrier layer. Examples of metals include gold, aluminium and chromium. For example, a layer of gold (e.g., having a thickness of 200 nm) may overlie the layer of superconducting material for aiding adhesion of wirebonds. A bilayer of aluminium and chromium may overlie a layer of niobium to provide a protective barrier against oxidation.

### Other Electrode Arrangements

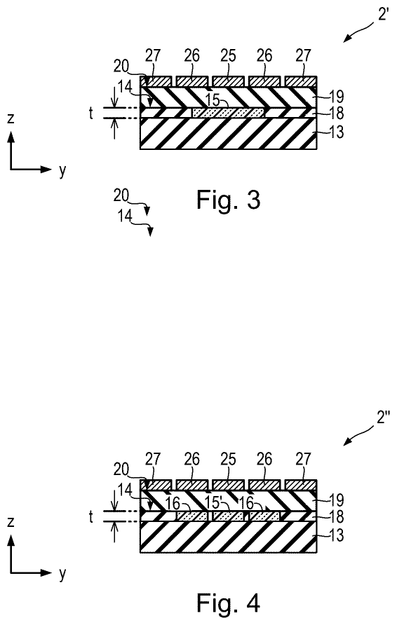

Referring to FIG. 3, a second surface-electrode trap 2′ is shown.

The surface-electrode trap 2′ comprises a substrate 13, for example, formed of magnesium oxide, having an upper surface 14 supporting a central superconducting strip 15, for instance formed of ReBCO, and a flanking layer 16 of dielectric material, such as silicon dioxide.

The superconducting strip 15 and dielectric layer 16 are covered by a further layer 19 of dielectric material, such as silicon dioxide, having an upper surface 20. The upper surface 20 of the dielectric material support an arrangement of electrodes 25, 26, 27 having the same configuration as the electrodes in the first surface-electrode trap 2 (FIG. 1) described earlier, but formed of normal metal, such as gold, silver or aluminium (in a normal state, above its critical temperature). The superconducting strip 15 runs under the central electrode 25 and inner portions of the RF electrodes 26. In other words, the superconducting strip 15 is wider than the central electrode 25.

Referring to FIG. 4, a third surface-electrode trap 2″ is shown.

The third surface-electrode trap 2″ is the same as the second surface-electrode trap 2′ except that the single, wide superconducting strip 15 (FIG. 3) is replaced by three, narrower superconducting strips 15′, 16 substantially coterminous (when viewed in from above) with the central electrode 25 and RF electrodes 26.

### Surface Electrodes Shielding

The surface-electrode traps hereinbefore described may include one or more antennas (not shown) disposed under the surface electrodes, in other words, interposed between the substrate and surface electrodes. An antenna may take the form of a current-carrying conductive track (or “wire”) which generates a magnetic field which can act on the trapped charged particles. A dielectric layer, such as silicon dioxide, having a thickness of, for example, between 1 μm and 10 μm, may be deposited over the antenna(s) so as to electrically isolate the antenna(s) and the surface electrodes, such that the dielectric layer is interposed between the antenna(s) and the surface electrodes.

Shielding effectiveness S in dB is defined as:

$$S = 20 {log}_{10} ( {B}_{0}^{′} / {B}_{1}^{′} ) \qquad ( 1 )$$

where B0′ is the magnetic field gradient at the charged particle in absence of the shielding structure, and B1′ is the magnetic field gradient at the charged particle in the presence of the shielding structure.

Shielding effectiveness can be divided into three regimes, namely:
“Low shielding”: S<1 dB (i.e., B1′>0.9 B0′)
“Intermediate shielding”: 20 dB≥S≥1 dB (i.e., 0.1 B0′≤B1′≤0.9 B0′)
“High shielding”: S>20 dB (i.e., B1′<0.1 B0′)

The surface electrodes are preferably arranged so as to not shield the charged particles from the antenna(s), in other words, to be low shielding. Intermediate shielding may, however, be acceptable.

Low shielding can be achieved by (a) choosing a suitable material for the electrodes and a thickness for the electrodes that is much smaller than the skin depth δ of the material (i.e., t<<δ) and (b) configuring the electrode layout to have, for example, slots and/or gaps.

Shielding effectiveness may be estimated by modelling the layer above the antenna as a solid ground plane of thickness t and electrical conductivity σ. For example, a layer of copper at room temperature having a thickness of 500 nm (t=500 nm and σ=5.96×10⁷ S/m) is considered to be a low shielding layer at frequency f=10 MHz since S<1 dB. A layer of copper with residual resistivity ratio RRR=100 at 4 Kelvin having a thickness of 5 μm (t=5 μm and σ=5.96×10⁷ S/m) is a high-shielding layer at a frequency f=300 MHz since S>20 dB.

Shielding effectiveness S is modified by electrode geometry, especially the presence of slots and cut-outs. Shielding effectiveness for a sheet without slots or cur-outs can, however, be used as approximate value.

### Operation

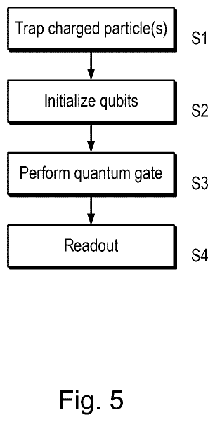

Referring to FIG. 5, a method of operating the quantum information processing system will now be described.

One or more charged particles 8 is (are) confined in the trap 2 (step S1) and initial qubit state(s) is (are) prepared (step S2). A sequence of one or more gates are applied to the qubit(s), for example, in the form of Pauli gate followed by a Clifford gate (step S3), and final state(s) are measured (step S4).

Examples of suitable operations can be found in T. P. Harty ibid. and R. Srinivas ibid. which are incorporated herein by reference. Reference is also made to H. Hsffner, C. Roos and R. Blatt “Quantum computing with trapped ions”: https://arxiv.org/pdf/0809.4368.pdf (2008) which is incorporated herein by reference.

During trapping, initialization and/or gate operation, a current I of at least 1 A is passed through one or more of the electrodes 5, 6.

Referring also to FIGS. 3 and 4, when performing a quantum gate (step S3), a high current (>1 A) oscillating at low frequency (<1 GHz) is applied to one or more of the three superconducting electrodes 15, 15′, 16. Simultaneously, a low current (<1 A) may be applied to one or more of the normal electrodes 25, 26 and/or to one or more of the superconducting electrodes 15, 15′, 16.

### Current-Carrying Electrode

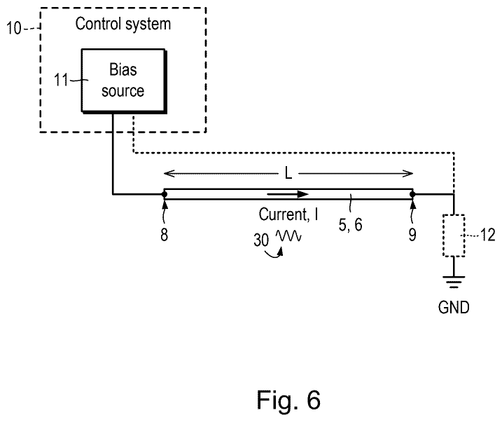

Referring to FIG. 6, a current-carrying electrode 5, 6 and the control system 10 are shown in more detail. Although the current-carrying electrode 5, 6 is shown as being straight, it need not be and can include, for example, bends and curved sections.

As hereinbefore described, the current-carrying electrode 5, 6 (which may be referred to as a “wire” or “trace”) is formed from superconducting material, such as rare-earth barium copper oxide, and has first and second ends 8, 9.

The first end 8 of the wire 5, 6 is connected to a bias source 11, such as current source or a voltage source, in the control system 10. The second end 9 of the wire 5, 6 is connected to ground GND, to a terminal load 12 or to the bias source 11 allowing current I to pass through the wire 5, 6. Connections are ohmic connections.

The control system 10 is configured to drive current through the wire 5, 6, between the so first and second ends 8, 9 of the wire such that the peak current is at least 1 A during trapping, initialization and/or gate operation. The current in a current-carrying electrode generates magnetic fields that are used to implement quantum gates.

The current I has a waveform 30 which is controlled over time by the control circuit 10. Configuration of a current-carrying electrode 5, 6 differs from a non-current-carrying electrode 7. For a non-current-carrying electrode 7, such as a DC electrode which is used to generate an electric field, there is only one input/output connection and so the control system 10 does not drive a current through the electrode.

If a current-carrying electrode 5, 6 is sufficiently short, then the current is approximately constant across the electrode. However, the voltage may vary between one end of a current-carrying electrode and another (dV=I Z, where Z is the electrode impedance). This is in contrast to a non-current-carrying electrode 7, where the voltage is approximately constant, but the current may vary across the electrode.

An electrode can be considered to be sufficiently short if it can be accurately modelled by an RLC circuit (when electrode length L is much smaller than wavelength). If a current-carrying electrode 5, 6 is sufficiently long to be considered a transmission line (that is, electrode length L is comparable or greater than wavelength), the current-carrying electrode 5, 6 may be viewed as a transmission line. Thus, the transmission line has first and second ends (or “end points”) with the second end terminated with a very low load (in other words, effectively shorted). Thus, applying power to the first end (or “input”) can result in an approximate voltage node and current anti-node at the ion trap. By contrast, for an elongate non-current carrying electrode, the end-point is effectively open. Thus, applying power at the input results in an approximate voltage anti-node and current node at the ion trap.

### Modifications

It will be appreciated that various modifications may be made to the embodiments hereinbefore described. Such modifications may involve equivalent and other features which are already known in the design, manufacture and use of charged particle traps and component parts thereof and which may be used instead of or in addition to features already described herein. Features of one embodiment may be replaced or supplemented by features of another embodiment.

The traps herein described have one layer of electrodes or two layers of electrodes (in which one of the layers of electrodes is buried). Traps with three or more layers (which include at least two buried layers of electrodes) may be used.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

Wherefore we claim:

1. A quantum information processing system comprising:
a charged particle trap comprising a substrate and a set of electrodes supported on the substrate; and
a control system for controlling the charged particle trap, for applying biases to the set of electrodes for trapping at least one charged particle and for performing at least one quantum logic gate on the at least one charged particle;
wherein the electrodes include at least one current-carrying electrode which is formed of a superconducting material, and the control system is configured to pass a current through the at least one current-carrying electrode having a peak current of at least 1 A.

2. The quantum information processing system of claim 1, wherein the control system is configured to pass the current having a frequency less than or equal to 1 GHz.

3. The quantum information processing system of claim 1, wherein the at least one current-carrying electrode has a thickness t of at least 0.3 μm.

4. The quantum information processing system of claim 1, wherein the superconducting material is rare-earth barium copper oxide, ReBCO.

5. The quantum information processing system of claim 1, wherein the at least one current-carrying electrode has a width w of between 5 and 500 μm.

6. The quantum information processing system of claim 1, wherein the charged particle trap comprises a first layer of co-planar electrodes and a second layer of co-planar electrodes, wherein the first layer of co-planar electrodes is interposed between the substrate and second layer of co-planar electrodes.

7. The quantum information processing system of claim 6, wherein the first layer of co-planar electrodes includes the at least one current-carrying electrode.

8. The quantum information processing system of claim 6, wherein the second layer of co-planar electrodes includes electrodes formed of normal material.

9. The quantum information processing system of claim 6, wherein the charged particle trap further comprise a layer of dielectric material interposed between the first layer of co-planar electrodes and the second layer of co-planar electrodes.

10. The quantum information processing system of claim 1, wherein the set of electrodes include a set of surface electrodes having a shielding effectiveness S=20 log₁₀[B0′/B1′]≤20 dB where B0′ would be the magnetic field gradient at a charged particle when trapped by the charged particle trap in absence of the set of surface electrodes, and B1′ would be the magnetic field gradient at a charged particle when trapped by the charged particle trap in the presence of the set of surface electrodes.

11. The quantum information processing system of claim 1, wherein a current-carrying electrode has first and second ends, and wherein the first end is connected to a bias source and the second end is connected to the bias source, to ground or a terminal load and wherein the control system is configured to pass the current through the at least one current-carrying electrode wire having a peak current of at least 1 A during trapping, initialization and/or gate operation.

12. A method of operating the quantum information processing system of claim 1, the method comprising:
trapping at least one charged particle in the trap, each charged particle providing a respective qubit;
preparing initial qubit state(s); and
applying a sequence of one or more gates to the qubit(s);
wherein applying the sequence of one or more gates to the qubit(s) includes driving current(s) through the, or each, of the at least current-carrying electrodes, the or each respective current having a peak current of at least 1 A.

13. The method of claim 12, wherein the or each respective current has a frequency less than or equal to 1 GHz.

14. The method of claim 12, wherein applying the sequence of one or more gates includes:
manipulating the qubit(s) using low-frequency radiation.

15. The method of claim 12, wherein applying the sequence of one or more gates includes:
performing a ZZ gate.

16. The method of claim 12, wherein applying the sequence of one or more gates includes:
performing a MS gate.

17. The method of claim 12, further comprising:
reading out qubit state(s).
